(19) United States
(12) Patent Application Publication
(10) Pub. No.: US 2026/0334006 A1
(43) Pub. Date: Oct. 22, 2026

(54) DISPLAY DEVICE AND ELECTRONIC DEVICE

(71) Applicant: Samsung Display Co., Ltd., Yongin-Si (KR)

(72) Inventors: JANGMI KANG, Yongin-si (KR); JINSEON KWAK, Yongin-si (KR); KYUNG-BAE KIM, Yongin-si (KR); KEONMIN OH, Yongin-si (KR); Yunjang Pyun, Yongin-si (KR)

(21) Appl. No.: 19/575,943

(22) Filed: Mar. 24, 2026

(30) Foreign Application Priority Data
Apr. 21, 2025 (KR) 10-2025-0051467

(51) Int. Cl. H10K 59/121

(52) U.S. Cl. CPC H10K 59/1213

(57) ABSTRACT

A display device includes a display panel including a plurality of pixels arranged in a first direction and a second direction intersecting the first direction, and a gate driver configured to provide a gate signal to the display panel and including a level shifter. The level shifter includes a first level shift circuit, a second level shift circuit adjacent to the first level shift circuit in the second direction, a first electrostatic discharge element electrically connected to the first level shift circuit, and a second electrostatic discharge element electrically connected to the second level shift circuit and adjacent to the first electrostatic discharge element in the first direction.

### CROSS-REFERENCE TO RELATED APPLICATIONS

This application claims priority under 35 USC § 119 to Korean Patent Application No. 10-2025-0051467 filed on Apr. 21, 2025, in the Korean Intellectual Property Office (KIPO), the entire disclosure of which is incorporated by reference herein.

### BACKGROUND

### FIELD

Embodiments relate to a display device and an electronic device. More specifically, embodiments relate to a display device that provides visual information and an electronic device including the display device.

### Description of the Related Art

A display device is a device that displays an image to provide visual information to a user. The display device may be operated by thin film transistors, capacitors, and a plurality of lines that are interconnected in a complex manner.

Recently, as demand for compact and high-resolution display devices increases, there is a growing need for efficient spatial arrangement, connection structures, and driving methods among the thin film transistors, the capacitors, and the lines included in the display device, as well as improving quality of displayed images.

### SUMMARY

Embodiments provide a display device that implements high resolution display of images.

Embodiments provide an electronic device including the display device.

A display device according to an embodiment of the present disclosure includes a display panel including a plurality of pixels arranged in a first direction and a second direction intersecting the first direction, and a gate driver configured to provide a gate signal to the display panel and the gate driver including a level shifter. The level shifter includes a first level shift circuit, a second level shift circuit adjacent to the first level shift circuit in the second direction, a first electrostatic discharge element electrically connected to the first level shift circuit, and a second electrostatic discharge element electrically connected to the second level shift circuit and adjacent to the first electrostatic discharge element in the first direction.

In an embodiment, the first level shift circuit may be arranged in a nth row of the plurality of pixels, the second level shift circuit may be arranged in a (n+1)th row of the plurality of pixels, and the first electrostatic discharge element and the second electrostatic discharge element may be arranged between the nth row and the (n+1)th row.

In an embodiment, the first level shift circuit may be electrically connected to a first pixel arranged in the nth row of the plurality of pixels, and the second level shift circuit may be electrically connected to a second pixel arranged in the (n+1)th row of the plurality of pixels.

In an embodiment, the first electrostatic discharge element may be arranged shifted toward the nth row, and the second electrostatic discharge element may be arranged shifted toward the (n+1)th row.

In an embodiment, the first electrostatic discharge element and the second electrostatic discharge element may be linearly arranged in the first direction.

In an embodiment, each of the first level shift circuit and the second level shift circuit may have a first length in the second direction, each of the first electrostatic discharge element and the second electrostatic discharge element may have a second length in the second direction, and the second length may be greater than the first length.

In an embodiment, the first direction may be a row direction, and the second direction may be a column direction.

In an embodiment, the first electrostatic discharge element and the second electrostatic discharge element may be arranged in alternating order in the first direction.

In an embodiment, the first electrostatic discharge element may include a first sub-element and a second sub-element, the second electrostatic discharge element may include a third sub-element and a fourth sub-element, and the first sub-element, the third sub-element, the second sub-element, and the fourth sub-element may be arranged in that sequence in the first direction.

In an embodiment, the display panel may include a silicon wafer substrate.

An electronic device according to an embodiment of the present disclosure includes a display device, and one or more processors configured to provide a control signal and input image data to the display device. The display device includes a display panel including a plurality of pixels arranged in a first direction and a second direction intersecting the first direction, and a gate driver configured to provide a gate signal to the display panel and the gate driver including a level shifter. The level shifter includes a first level shift circuit, a second level shift circuit adjacent to the first level shift circuit in the second direction, a first electrostatic discharge element electrically connected to the first level shift circuit, and a second electrostatic discharge element electrically connected to the second level shift circuit and adjacent to the first electrostatic discharge element in the first direction.

In an embodiment, the first level shift circuit may be arranged in a nth row, the second level shift circuit may be arranged in a (n+1)th row, and the first electrostatic discharge element and the second electrostatic discharge element may be arranged between the nth row and the (n+1)th row.

In an embodiment, the first level shift circuit may be electrically connected to a first pixel arranged in the nth row of the plurality of pixels, and the second level shift circuit may be electrically connected to a second pixel arranged in the (n+1)th row of the plurality of pixels.

In an embodiment, the first electrostatic discharge element may be arranged shifted toward the nth row, and the second electrostatic discharge element may be arranged shifted toward the (n+1)th row.

In an embodiment, the first electrostatic discharge element and the second electrostatic discharge element may be linearly arranged in the first direction.

In an embodiment, each of the first level shift circuit and the second level shift circuit may have a first length in the second direction, each of the first electrostatic discharge element and the second electrostatic discharge element may have a second length in the second direction, and the second length may be greater than the first length.

In an embodiment, the first direction may be a row direction, and the second direction may be a column direction.

In an embodiment, the first electrostatic discharge element and the second electrostatic discharge element may be arranged in alternating order in the first direction.

In an embodiment, the first electrostatic discharge element may include a first sub-element and a second sub-element, the second electrostatic discharge element may include a third sub-element and a fourth sub-element, and the first sub-element, the third sub-element, the second sub-element, and the fourth sub-element may be sequentially arranged in the first direction.

In an embodiment, the display panel may include a silicon wafer substrate.

In a display device according to embodiments of the present disclosure, the display device may include a gate driver including a level shifter including a level shift circuit and an electrostatic discharge element. Two rows of level shift circuits may be arranged in a column direction, and electrostatic discharge elements electrically connected to the respective two rows of level shift circuits may be arranged in a row direction. Accordingly, a pitch of a row of pixels and a pitch of a gate driver electrically connected thereto may correspond to each other, and the display device may be implemented with high resolution.

### BRIEF DESCRIPTION OF THE DRAWINGS

FIG. 1 is a plan view illustrating a display device according to an embodiment of the present disclosure.

FIG. 2 is a block diagram illustrating the display device of FIG. 1.

FIG. 3 is a circuit diagram illustrating an example of a pixel included in the display device of FIG. 1.

FIG. 4 is a block diagram illustrating an example of a gate driver included in the display device of FIG. 1.

FIG. 5 is a block diagram illustrating an example of a gate driver included in the display device of FIG. 1.

FIG. 6 is a block diagram illustrating an example of a level shifter included in the gate driver of FIG. 5.

FIG. 7 is a block diagram illustrating an example of a level shifter included in the gate driver of FIG. 5.

FIG. 8 is a block diagram illustrating an example of a level shifter included in the gate driver of FIG. 5.

FIG. 9 is a cross-sectional view illustrating an example of a display panel included in the display device of FIG. 1.

FIG. 10 is a block diagram illustrating an electronic device according to an embodiment of the present disclosure.

FIG. 11 is a schematic view illustrating electronic devices according to embodiments of the present disclosure.

### DETAILED DESCRIPTION OF THE EMBODIMENTS

Hereinafter, embodiments of the present disclosure will be described in more detail with reference to the accompanying drawings. The same reference numerals are used for the same components in the drawings, and redundant descriptions of the same components will be omitted.

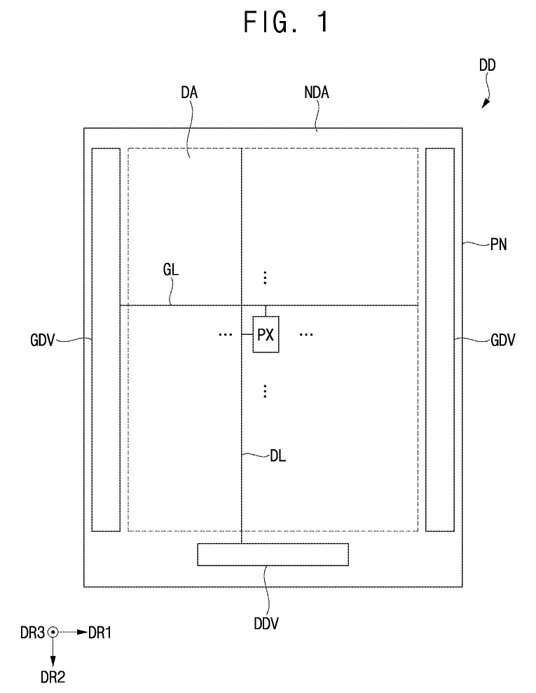

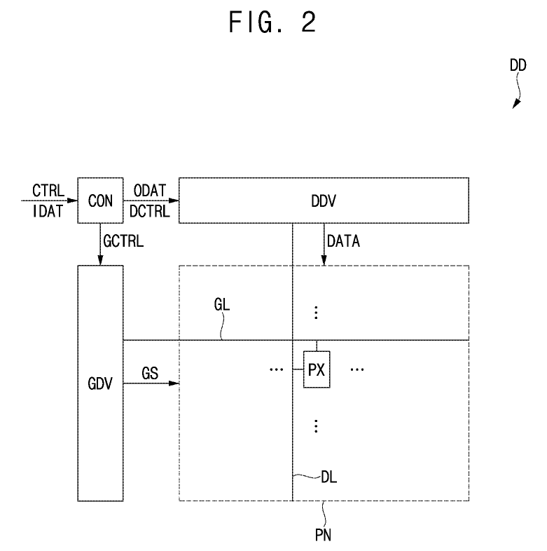

FIG. 1 is a plan view illustrating a display device according to an embodiment of the present disclosure. FIG. 2 is a block diagram illustrating the display device of FIG. 1.

Referring to FIGS. 1 and 2, a display device DD may include a display panel PN and a driver that drives the display panel PN. The display panel PN may include a display area DA and a non-display area NDA.

The display area DA may be an area that displays an image. A plurality of pixels PX may be arranged in the display area DA. For example, the pixels PX may be repeatedly arranged along a first direction DR1 and a second direction DR2 intersecting the first direction DR1. As each of the pixels PX emits light, the display area DA may display an image. For example, the display area DA may display an image in a third direction DR3 intersecting each of the first direction DR1 and the second direction DR2.

The non-display area NDA may be an area that does not display an image. The non-display area NDA may be arranged around the display area DA. For example, the non-display area NDA may surround the display area DA in a plan view. The driver may be arranged in the non-display area NDA. For example, the driver may provide signals and/or voltages to the pixels PX. For example, the driver may include a gate driver GDV, a data driver DDV, and a controller CON.

Each of the pixels PX may be electrically connected to the gate driver GDV and the data driver DDV. Each of the pixels PX may be electrically connected to the gate driver GDV through a gate line GL, and may be electrically connected to the data driver DDV through a data line DL. Accordingly, each of the pixels PX may receive a gate signal GS and a data voltage DATA.

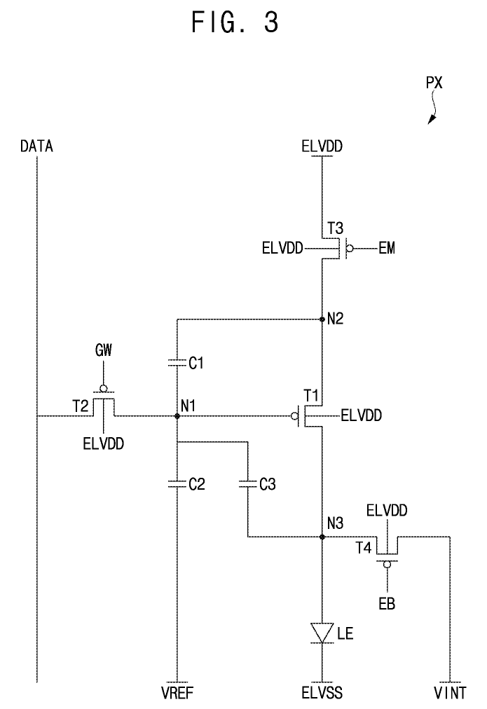

The gate driver GDV may receive a gate control signal GCTRL from the controller CON. The gate driver GDV may generate the gate signal GS based on the gate control signal GCTRL. The gate signal GS may be provided to each of the pixels PX through the gate line GL. For example, the gate signal GS may include a write gate signal (e.g., a write gate signal GW of FIG. 3), an initialization gate signal (e.g., an initialization gate signal EB of FIG. 3), and a light emitting signal (e.g., a light emitting signal EM of FIG. 3).

The data driver DDV may receive a data control signal DCTRL and output image data ODAT from the controller CON. The data driver DDV may generate the data voltage DATA based on the data control signal DCTRL and the output image data ODAT. The data voltage DATA may be provided to each of the pixels PX through the data line DL.

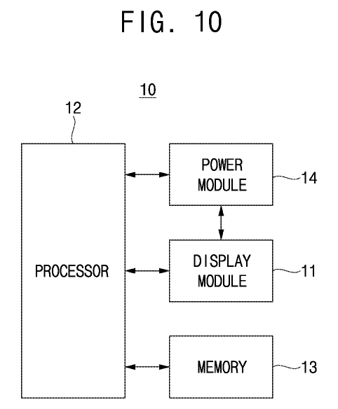

The controller CON may receive a control signal CTRL and input image data IDAT from an external device (e.g., a processor 12 of FIG. 10). The controller CON may generate the gate control signal GCTRL, the data control signal DCTRL, and the output image data ODAT based on the control signal CTRL and the input image data IDAT. The controller CON may control the gate driver GDV and the data driver DDV.

Although FIG. 1 illustrates that the gate driver GDV is arranged at a first side and a second side opposite to the first side of the display device DD, the present disclosure is not limited thereto. For example, the gate driver GDV may be arranged at the first side or the second side of the display device DD.

FIG. 3 is a circuit diagram illustrating an example of a pixel included in the display device of FIG. 1.

Referring to FIG. 3, the pixel PX may include a first transistor T1, a second transistor T2, a third transistor T3, a fourth transistor T4, a first capacitor C1, a second capacitor C2, a third capacitor C3, and a light emitting element LE.

The first transistor T1 may include a gate electrode connected to a first node N1, a first electrode connected to a second node N2, and a second electrode connected to a third node N3. The first transistor T1 may generate a driving current applied to the light emitting element LE based on a voltage difference between the first node N1 and the second node N2.

The second transistor T2 may include a gate electrode that receives a write gate signal GW, a first electrode that receives a data voltage DATA, and a second electrode connected to the first node N1. The second transistor T2 may be turned on in response to the write gate signal GW to provide the data voltage DATA to the first node N1.

The third transistor T3 may include a gate electrode that receives a light emitting signal EM, a first electrode that receives a first power voltage ELVDD, and a second electrode connected to the second node N2. The third transistor T3 may be turned on in response to the light emitting signal EM to provide the first power voltage ELVDD to the second node N2.

The fourth transistor T4 may include a gate electrode that receives an initialization gate signal EB, a first electrode that receives an initialization voltage VINT, and a second electrode connected to the third node N3. The fourth transistor T4 may be turned on in response to the initialization gate signal EB to provide the initialization voltage VINT to the third node N3.

Each of the first, second, third, and fourth transistors T1, T2, T3, and T4 may further include a back gate electrode that receives the first power voltage ELVDD.

The first capacitor C1 may include a first electrode connected to the first node N1 and a second electrode connected to the second node N2. The second capacitor C2 may include a first electrode connected to the first node N1 and a second electrode that receives a reference voltage VREF. The third capacitor C3 may include a first electrode connected to the first node N1 and a second electrode connected to the third node N3.

The light emitting element LE may include a first electrode (e.g., an anode) connected to the third node N3 and a second electrode (e.g., a cathode) that receives a second power voltage ELVSS. The second power voltage ELVSS may be a voltage lower than the first power voltage ELVDD. The light emitting element LE may emit light based on the driving current generated by the first transistor T1.

Although FIG. 3 illustrates that the pixel PX includes four transistors T1, T2, T3, and T4, three capacitors C1, C2, and C3, and one light emitting element LE, this is merely illustrative and the present disclosure is not limited thereto. For example, the pixel PX may include one or more transistors, one or more capacitors, and one or more light emitting elements.

In addition, although FIG. 3 illustrates that each of the first, second, third, and fourth transistors T1, T2, T3, and T4 is a p-type transistor (e.g., a PMOS transistor), this is merely illustrative and the present disclosure is not limited thereto. For example, at least one of the first, second, third, and fourth transistors T1, T2, T3, and T4 may be an n-type transistor (e.g., an NMOS transistor).

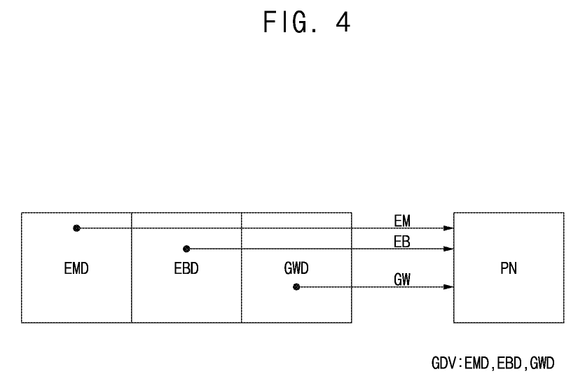

FIG. 4 is a block diagram illustrating an example of a gate driver included in the display device of FIG. 1.

Referring to FIGS. 1 and 4, the gate driver GDV may include a plurality of drivers.

In an embodiment, the gate driver GDV may include a light emitting driver EMD, an initialization gate driver EBD, and a write gate driver GWD. For example, the light emitting driver EMD, the initialization gate driver EBD, and the write gate driver GWD may be arranged in one direction (e.g., the first direction DR1).

The light emitting driver EMD may generate the light emitting signal EM, and provide the light emitting signal EM to the pixels PX of the display panel PN. The initialization gate driver EBD may generate the initialization gate signal EB, and may provide the initialization gate signal EB to the pixels PX of the display panel PN. The write gate driver GWD may generate the write gate signal GW, and may provide the write gate signal GW to the pixels PX of the display panel PN.

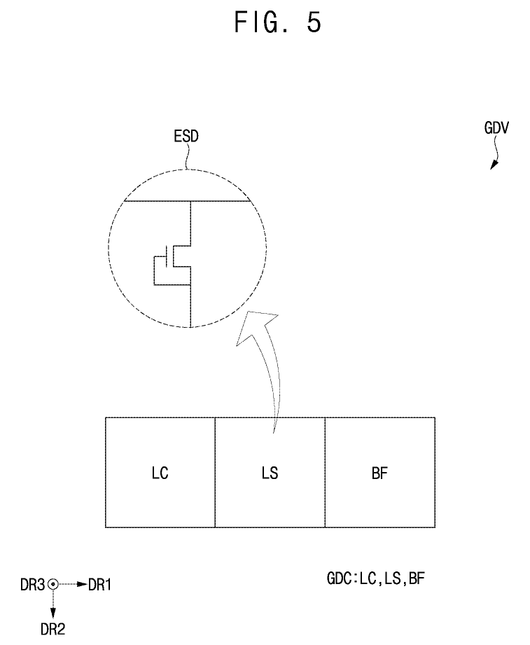

FIG. 5 is a block diagram illustrating an example of a gate driver included in the display device of FIG. 1.

Referring to FIG. 5, the gate driver GDV may include a gate driving circuit GDC. The gate driving circuit GDC may include a logic unit LC, a level shifter LS, and an output buffer BF. Each of the logic unit LC, the level shifter LS, and the output buffer BF may include at least one transistor. For example, the logic unit LC, the level shifter LS, and the output buffer BF may be arranged in one direction (e.g., the first direction DR1).

The logic unit LC may generate an input signal, and may provide the input signal to the level shifter LS. The level shifter LS may convert the input signal having a low voltage level into an output signal having a high voltage level, and may provide the output signal to the output buffer BF. The output buffer BF may output the output signal.

In an embodiment, the level shifter LS may include an electrostatic discharge element ESD. The electrostatic discharge element ESD may protect an internal circuit of the level shifter LS from electrostatic discharge. The electrostatic discharge element ESD may provide an electrostatic discharge path to protect the internal circuit when electrostatic discharge occurs. For example, the electrostatic discharge element ESD may be an element having a grounded-gate NMOS (GGNMOS) structure in which a gate electrode and a source electrode are connected to a ground pad. For example, the electrostatic discharge element ESD may discharge static electricity that may occur between a low-voltage level element and a medium-voltage level element inside the level shifter LS to the ground pad.

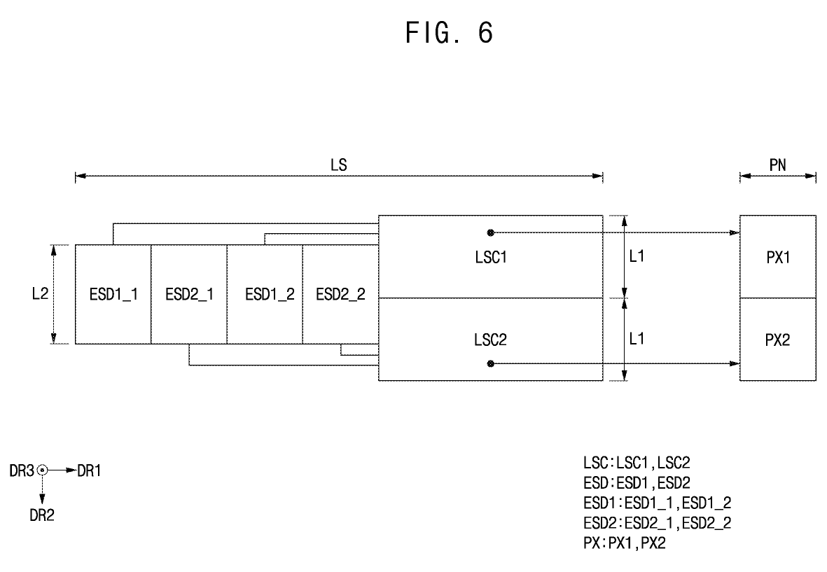

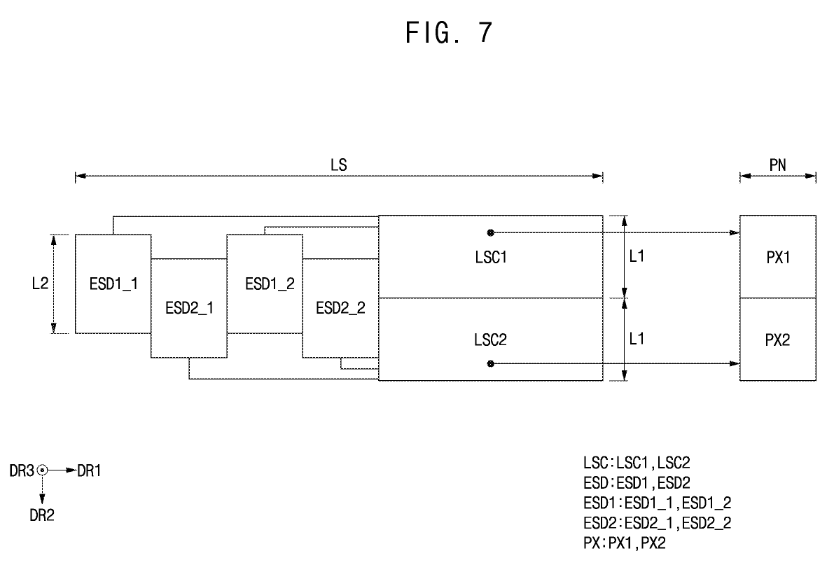

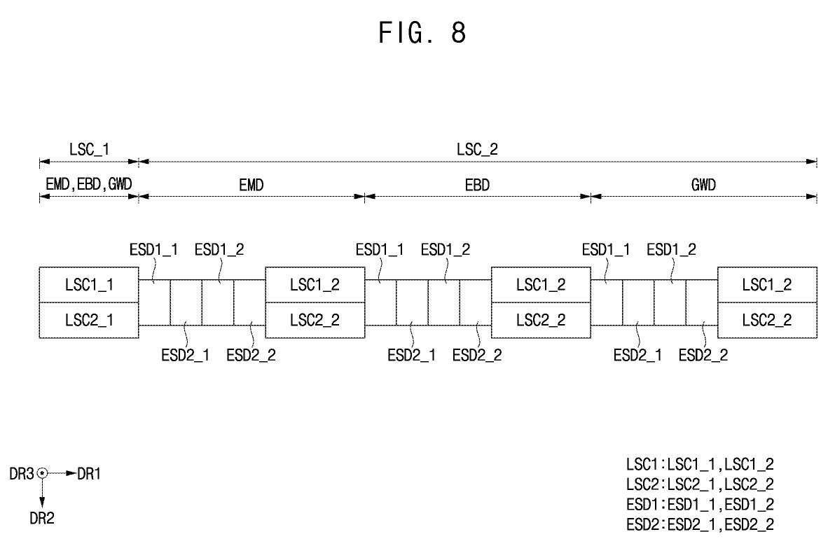

FIG. 6 is a block diagram illustrating an example of a level shifter included in the gate driver of FIG. 5. FIG. 7 is a block diagram illustrating an example of a level shifter included in the gate driver of FIG. 5. FIG. 8 is a block diagram illustrating an example of a level shifter included in the gate driver of FIG. 5.

Referring to FIGS. 5, 6 and 7, the level shifter LS may include a level shift circuit LSC and the electrostatic discharge element ESD. For example, the level shift circuit LSC may be adjacent to the electrostatic discharge element ESD in the first direction DR1.

The level shift circuit LSC may be electrically connected to the pixels PX arranged in the display panel PN. The level shift circuit LSC may include a first level shift circuit LSC1 and a second level shift circuit LSC2.

The first level shift circuit LSC1 may be a circuit arranged in a nth (where n is a natural number) row of the level shift circuit LSC, and the second level shift circuit LSC2 may be a circuit arranged in a (n+1)th row of the level shift circuit LSC. The first level shift circuit LSC1 may be electrically connected to a first pixel PX1 arranged in the nth row of the pixels PX, and the second level shift circuit LSC2 may be electrically connected to a second pixel PX2 arranged in the (n+1)th row of the pixels PX.

The arrangement of the first level shift circuit LSC1 may correspond to the arrangement of the first pixel PX1, and the arrangement of the second level shift circuit LSC2 may correspond to the arrangement of the second pixel PX2. For example, the first level shift circuit LSC1 and the first pixel PX1 may be arranged in a first row, and the second level shift circuit LSC2 and the second pixel PX2 may be arranged in a second row. The first and second level shift circuits LSC1 and LSC2 may be arranged in alternating order along the second direction DR2, and the first and second pixels PX1 and PX2 may be arranged in alternating order along the second direction DR2. For example, the second direction DR2 may be a column direction.

The electrostatic discharge element ESD may include a first electrostatic discharge element ESD1 and a second electrostatic discharge element ESD2. The first electrostatic discharge element ESD1 may be electrically connected to the first level shift circuit LSC1, and the second electrostatic discharge element ESD2 may be electrically connected to the second level shift circuit LSC2.

The first electrostatic discharge element ESD1 may define one level shifter LS together with the first level shift circuit LSC1. For example, the first level shift circuit LSC1 and the first electrostatic discharge element ESD1 may define a level shifter LS electrically connected to the first pixel PX1 arranged in the nth row. The second electrostatic discharge element ESD2 may define one level shifter LS together with the second level shift circuit LSC2. For example, the second level shift circuit LSC2 and the second electrostatic discharge element ESD2 may define a level shifter LS electrically connected to the second pixel PX2 arranged in the (n+1)th row.

In an embodiment, each of the first electrostatic discharge element ESD1 and the second electrostatic discharge element ESD2 may include a plurality of elements. For example, the first electrostatic discharge element ESD1 may include a first sub-element ESD1_1 and a second sub-element ESD1_2, and the second electrostatic discharge element ESD2 may include a third sub-element ESD2_1 and a fourth sub-element ESD2_2. Each of the first and second sub-elements ESD1_1 and ESD1_2 may be electrically connected to the first level shift circuit LSC1, and each of the third and fourth sub-elements ESD2_1 and ESD2_2 may be electrically connected to the second level shift circuit LSC2. However, the present disclosure is not limited thereto, and each of the first and second electrostatic discharge elements ESD1 and ESD2 may include one or more elements.

In an embodiment, the first electrostatic discharge element ESD1, which is electrically connected to the first level shift circuit LSC1 arranged in the nth row, and the second electrostatic discharge element ESD2, which is electrically connected to the second level shift circuit LSC2 arranged in the (n+1)th row, may be arranged side by side in the first direction DR1. The first electrostatic discharge element ESD1 and the second electrostatic discharge element ESD2 may be arranged in the first direction DR1. For example, the first direction DR1 may be a row direction.

The first and second electrostatic discharge elements ESD1 and ESD2 may be arranged between two rows (i.e., the nth row and the (n+1)th row). For example, the first and second electrostatic discharge elements ESD1 and ESD2 may be arranged between the first level shift circuit LSC1 and the second level shift circuit LSC2 in a plan view. That is, the first and second level shift circuits LSC1 and LSC2 may be arranged along the second direction DR2 (e.g., the column direction), and the first and second electrostatic discharge elements ESD1 and ESD2 may be arranged along the first direction DR1 (e.g., the row direction).

In an embodiment, the elements included in the first electrostatic discharge element ESD1 and the elements included in the second electrostatic discharge element ESD2 may be arranged in alternating order in the first direction DR1. For example, the first sub-element ESD1_1, the third sub-element ESD2_1, the second sub-element ESD1_2, and the fourth sub-element ESD2_2 may be sequentially arranged in the first direction DR1. However, the present disclosure is not limited thereto, and the arrangement of the elements included in the first and second electrostatic discharge elements ESD1 and ESD2 may be variously modified.

The level shift circuit LSC (i.e., each of the first and second level shift circuits LSC1 and LSC2) may have a first length L1 in the second direction DR2. The electrostatic discharge element ESD (i.e., each of the first and second electrostatic discharge elements ESD1 and ESD2, or each of the first, second, third, and fourth sub-elements ESD1_1, ESD1_2, ESD2_1, and ESD2_2) may have a second length L2 in the second direction DR2. In an embodiment, the second length L2 may be greater than the first length L1. In addition, the second length L2 may be less than twice the first length L1. For example, the first length L1 may be about 5.10 micrometers (µm), and the second length L2 may be 5.94 µm, but this is merely illustrative, and the present disclosure is not limited thereto.

As the second length L2 of the electrostatic discharge element ESD is greater than the first length L1 of the level shift circuit LSC, when the first and second electrostatic discharge elements ESD1 and ESD2 are arranged to correspond to the arrangement of the first and second level shift circuits LSC1 and LSC2, an area occupied by the level shifter LS may increase so that the arrangement of the level shifter LS may not correspond to the arrangement of the pixels PX. That is, when the first and second electrostatic discharge elements ESD1 and ESD2 are also arranged in the second direction DR2, like the first and second level shift circuits LSC1 and LSC2, a pitch (e.g., a length in the second direction DR2) of one level shifter LS (or one gate driver GDV) may not correspond to a pitch (e.g., a length in the second direction DR2) of one pixel PX (or one row of pixels PX), so that dead space may increase.

Therefore, in an embodiment of the present disclosure, the first and second electrostatic discharge elements ESD1 and ESD2, which have the second length L2 greater than the first length L1 of the level shift circuit LSC, may be arranged in the first direction DR1 between two rows of the level shift circuit LSC. Accordingly, the pitch of one level shifter LS (or one gate driver GDV) may correspond to the pitch of one pixel PX (or one row of pixels PX), and dead space may be reduced.

In an embodiment, as illustrated in FIG. 6, the first and second electrostatic discharge elements ESD1 and ESD2 may be linearly arranged in the first direction DR1.

In an embodiment, as illustrated in FIG. 7, the first and second electrostatic discharge elements ESD1 and ESD2 may be arranged in a zigzag pattern along the first direction DR1. The first electrostatic discharge element ESD1 (e.g., the first and second sub-elements ESD1_1 and ESD1_2) may be arranged shifted toward the nth row in which the first level shift circuit LSC1 is arranged (e.g., toward a direction opposite to the second direction DR2), and the second electrostatic discharge element ESD2 (e.g., the third and fourth sub-elements ESD2_1 and ESD2_2) may be arranged shifted toward the (n+1)th row in which the second level shift circuit LSC2 is arranged (e.g., toward the second direction DR2). In this case, it may be easy to form a line electrically connecting the first electrostatic discharge element ESD1 and the first level shift circuit LSC1 and a line electrically connecting the second electrostatic discharge element ESD2 and the second level shift circuit LSC2.

Referring further to FIG. 8, the level shifter LS may include a first circuit LSC_1 and a second circuit LSC_2. For example, the first circuit LSC_1 and the second circuit LSC_2 may be adjacent in the first direction DR1. For example, the first circuit LSC_1 may include a low-voltage (LV) level element, and the second circuit LSC_2 may include a middle-voltage (MV) level element.

The first circuit LSC_1 may include a first sub-circuit LSC1_1 and a second sub-circuit LSC2_1. The first sub-circuit LSC1_1 may be a circuit arranged in the nth row of the first circuit LSC_1, and the second sub-circuit LSC2_1 may be a circuit arranged in the (n+1)th row of the first circuit LSC_1. The first and second sub-circuits LSC1_1 and LSC2_1 may be arranged in alternating order along the second direction DR2.

The second circuit LSC_2 may include a third sub-circuit LSC1_2 and a fourth sub-circuit LSC2_2. The third sub-circuit LSC1_2 may be a circuit arranged in the nth row of the second circuit LSC_2, and the fourth sub-circuit LSC2_2 may be a circuit arranged in the (n+1)th row of the second circuit LSC_2. The third and fourth sub-circuits LSC1_2 and LSC2_2 may be arranged in alternating order along the second direction DR2.

In an embodiment, the first sub-circuit LSC1_1 and the third sub-circuit LSC1_2 may be included in the first level shift circuit LSC1, and the second sub-circuit LSC2_1 and the fourth sub-circuit LSC2_2 may be included in the second level shift circuit LSC2.

In an embodiment, the second circuit LSC_2 may include the electrostatic discharge element ESD. The first electrostatic discharge element ESD1 (e.g., each of the first and second sub-elements ESD1_1 and ESD1_2) may be electrically connected to the first and third sub-circuits LSC1_1 and LSC1_2, and the second electrostatic discharge element ESD2 (e.g., each of the third and fourth sub-elements ESD2_1 and ESD2_2) may be electrically connected to the second and fourth sub-circuits LSC2_1 and LSC2_2.

The first electrostatic discharge element ESD1, which is electrically connected to the first and third sub-circuits LSC1_1 and LSC1_2 arranged in the nth row, and the second electrostatic discharge element ESD2, which is electrically connected to the second and fourth sub-circuits LSC2_1 and LSC2_2 arranged in the (n+1)th row, may be arranged in the first direction DR1. The first and second electrostatic discharge elements ESD1 and ESD2 may be arranged between two rows (i.e., the nth row and the (n+1)th row). For example, the first and second electrostatic discharge elements ESD1 and ESD2 may be arranged between the third sub-circuit LSC1_2 and the fourth sub-circuit LSC2_2 in a plan view. That is, the first and second sub-circuits LSC1_1 and LSC2_1 may be arranged along the second direction DR2, the third and fourth sub-circuits LSC1_2 and LSC2_2 may be arranged along the second direction DR2, and the first and second electrostatic discharge elements ESD1 and ESD2 may be arranged along the first direction DR1.

Each of the plurality of drivers included in the gate driver GDV may include the level shifter LS. For example, each of the light emitting driver EMD, the initialization gate driver EBD, and the write gate driver GWD may include the level shifter LS, and may constitute the first circuit LSC_1 and the second circuit LSC_2.

The light emitting driver EMD may include the first and second sub-circuits LSC1_1 and LSC2_1 of the first circuit LSC_1, the third and fourth sub-circuits LSC1_2 and LSC2_2 of the second circuit LSC_2, and the first and second electrostatic discharge elements ESD1 and ESD2. The initialization gate driver EBD may include the first and second sub-circuits LSC1_1 and LSC2_1 of the first circuit LSC_1, the third and fourth sub-circuits LSC1_2 and LSC2_2 of the second circuit LSC_2, and the first and second electrostatic discharge elements ESD1 and ESD2. The write gate driver GWD may include the first and second sub-circuits LSC1_1 and LSC2_1 of the first circuit LSC_1, the third and fourth sub-circuits LSC1_2 and LSC2_2 of the second circuit LSC_2, and the first and second electrostatic discharge elements ESD1 and ESD2.

For example, the first circuit LSC_1 of the light emitting driver EMD, the first circuit LSC_1 of the initialization gate driver EBD, the first circuit LSC_1 of the write gate driver GWD, the second circuit LSC_2 of the light emitting driver EMD, the second circuit LSC_2 of the initialization gate driver EBD, and the second circuit LSC_2 of the write gate driver GWD may be arranged along the first direction DR1.

For example, in the first circuit LSC_1, the first and second sub-circuits LSC1_1 and LSC2_1 of the light emitting driver EMD, the first and second sub-circuits LSC1_1 and LSC2_1 of the initialization gate driver EBD, and the first and second sub-circuits LSC1_1 and LSC2_1 of the write gate driver GWD may be arranged along the first direction DR1.

For example, in the second circuit LSC_2, the electrostatic discharge element ESD of the light emitting driver EMD, the third and fourth sub-circuits LSC1_2 and LSC2_2 of the light emitting driver EMD, the electrostatic discharge element ESD of the initialization gate driver EBD, the third and fourth sub-circuits LSC1_2 and LSC2_2 of the initialization gate driver EBD, the electrostatic discharge element ESD of the write gate driver GWD, and the third and fourth sub-circuits LSC1_2 and LSC2_2 of the write gate driver GWD may be arranged along the first direction DR1.

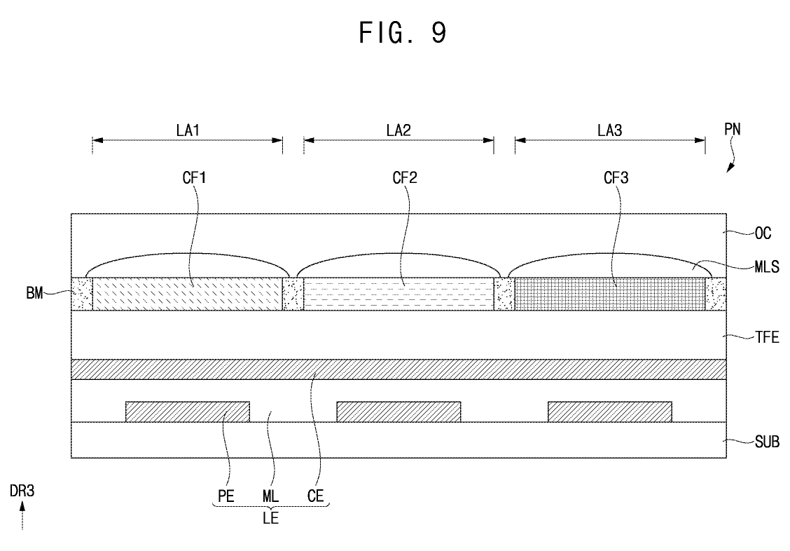

FIG. 9 is a cross-sectional view illustrating an example of a display panel included in the display device of FIG. 1.

Referring to FIGS. 1 and 9, the display panel PN included in the display device DD may define a first light emitting area LA1, a second light emitting area LA2, and a third light emitting area LA3.

Each of the first, second, and third light emitting areas LA1, LA2, and LA3 may refer to an area in which light emitted from the light emitting element LE included in the display device DD is emitted to outside of the display device DD. The first, second, and third light emitting areas LA1, LA2, and LA3 may emit light in different wavelength bands. For example, the first light emitting area LA1 may emit light in a red wavelength band, the second light emitting area LA2 may emit light in a green wavelength band, and the third light emitting area LA3 may emit light in a blue wavelength band, but the present disclosure is not limited thereto.

The display panel PN may include a substrate SUB, the light emitting element LE, an encapsulation layer TFE, a bank BM, a first color filter CF1, a second color filter CF2, a third color filter CF3, a micro lens MLS, and a planarization layer OC. The light emitting element LE may include a pixel electrode PE, an intermediate layer ML, and a common electrode CE.

The substrate SUB may include a transparent material or an opaque material. Examples of the material that may be used as the substrate SUB may include silicon, polyimide, quartz, glass, or the like. These materials may be used alone or in combination with each other. In an embodiment, the substrate SUB may be a silicon wafer substrate. The substrate SUB may be a semiconductor circuit substrate. The substrate SUB may include a base substrate and a plurality of pixel circuits accommodated in the base substrate. Each of the pixel circuits may include at least one transistor (e.g., the first, second, third, and fourth transistors T1, T2, T3, and T4 of FIG. 3).

The pixel electrode PE may be arranged on the substrate SUB. The pixel electrode PE may be arranged in each of the first, second, and third light emitting areas LA1, LA2, and LA3 on the substrate SUB. The pixel electrode PE may be electrically connected to the transistor included in each of the pixel circuits. The pixel electrode PE may include a metal, an alloy, a conductive metal nitride, a conductive metal oxide, a transparent conductive material, or the like. These may be used alone or in combination with each other.

The intermediate layer ML may be arranged on the pixel electrode PE. In an embodiment, the intermediate layer ML may include a material that emits light. The intermediate layer ML may include at least one light emitting layer and at least one auxiliary layer arranged below or above the light emitting layer. For example, the light emitting layer may include a material that emits light of a selected color, and the auxiliary layer may include at least one of a hole injection layer, a hole transport layer, an electron injection layer, and an electron transport layer.

The common electrode CE may be arranged on the intermediate layer ML. For example, the common electrode CE may extend continuously across the first, second, and third light emitting areas LA1, LA2, and LA3. The common electrode CE may include a metal, an alloy, a conductive metal nitride, a conductive metal oxide, a transparent conductive material, or the like. These may be used alone or in combination with each other.

Accordingly, the light emitting element LE including the pixel electrode PE, the intermediate layer ML, and the common electrode CE may be arranged in each of the first, second, and third light emitting areas LA1, LA2, and LA3 on the substrate SUB. Light may be emitted from each of the first, second, and third light emitting areas LA1, LA2, and LA3 as the intermediate layer ML emits light based on a voltage difference between the pixel electrode PE and the common electrode CE.

The encapsulation layer TFE may be arranged on the common electrode CE. The encapsulation layer TFE may include at least one inorganic encapsulation layer and at least one organic encapsulation layer. For example, the encapsulation layer TFE may include a first inorganic layer, an organic layer, and a second inorganic layer sequentially stacked, but the present disclosure is not limited thereto. The encapsulation layer TFE may prevent foreign substances from penetrating into the light emitting element LE.

The bank BM may be arranged on the encapsulation layer TFE. The bank BM may define the first, second, and third light emitting areas LA1, LA2, and LA3. For example, the bank BM may define a plurality of openings that partition the first, second, and third light emitting areas LA1, LA2, and LA3. The plurality of openings may respectively overlap the first, second, and third light emitting areas LA1, LA2, and LA3 in a plan view.

In an embodiment, the bank BM may include a light blocking material. Examples of the light blocking material may include an organic material or an inorganic material containing a black pigment or a black dye. However, the present disclosure is not limited thereto, and the bank BM may include a reflective material such as a metal material. Accordingly, the bank BM may prevent color mixing between the first, second, and third light emitting areas LA1, LA2, and LA3.

The first, second, and third color filters CF1, CF2, and CF3 may be arranged on the encapsulation layer TFE, and may be respectively arranged in the plurality of openings defined by the bank BM. The first color filter CF1 may be arranged in the opening of the first light emitting area LA1, the second color filter CF2 may be arranged in the opening of the second light emitting area LA2, and the third color filter CF3 may be arranged in the opening of the third light emitting area LA3.

Each of the first, second, and third color filters CF1, CF2, and CF3 may selectively transmit light of a specific wavelength band and absorb light of a remaining wavelength band. The first, second, and third color filters CF1, CF2, and CF3 may selectively transmit light in different wavelength bands. Accordingly, light in a wavelength band selectively transmitted by the first, second, and third color filters CF1, CF2, and CF3 may be emitted from the first, second, and third light emitting areas LA1, LA2, and LA3, respectively.

For example, the first color filter CF1 may selectively transmit light in a red wavelength band, the second color filter CF2 may selectively transmit light in a green wavelength band, and the third color filter CF3 may selectively transmit light in a blue wavelength band. Accordingly, light in a red wavelength band may be emitted from the first light emitting area LA1, light in a green wavelength band may be emitted from the second light emitting area LA2, and light in a blue wavelength band may be emitted from the third light emitting area LA3, but the present disclosure is not limited thereto.

The micro lens MLS may be arranged on the first, second, and third color filters CF1, CF2, and CF3. The micro lens MLS may have a selected refractive index, and may improve light extraction efficiency.

The planarization layer OC may be arranged on the micro lens MLS. The planarization layer OC may include an organic material or an inorganic material. The planarization layer OC may compensate for a step caused by components arranged below the planarization layer OC (e.g., the first, second, and third color filters CF1, CF2, and CF3, the micro lens MLS, or the like).

The display device DD according to an embodiment of the present disclosure may include the gate driver GDV including the level shifter LS including the level shift circuit LSC and the electrostatic discharge element ESD. The second length L2 of the electrostatic discharge element ESD may be greater than the first length L1 of the level shift circuit LSC. The first and second level shift circuits LSC1 and LSC2 may be arranged in the second direction DR2, and the first and second electrostatic discharge elements ESD1 and ESD2, which are electrically connected to the first and second level shift circuits LSC1 and LSC2, respectively, may be arranged in the first direction DR1. Accordingly, a pitch of one level shifter LS (or one gate driver GDV) may correspond to a pitch of one pixel PX (or one row of pixels PX), and dead space of the display device DD may be reduced, so that the display device DD may be implemented with high resolution.

The display device DD according to embodiments of the present disclosure may be applied to various electronic devices. An electronic device according to an embodiment of the present disclosure may include the display device described above, and may further include a module or device having other additional functions in addition to the display device.

FIG. 10 is a block diagram illustrating an electronic device according to an embodiment of the present disclosure.

Referring to FIG. 10, an electronic device 10 may include a display module 11, a processor 12, a memory 13, and a power module 14.

The processor 12 may include at least one of a central processing unit (CPU), an application processor (AP), a graphic processing unit (GPU), a communication processor (CP), and an image signal processor (ISP). The processor 12 may provide a control signal (e.g., the control signal CTRL of FIG. 2) and input image data (e.g., the input image data IDAT of FIG. 2) to a controller (e.g., the controller CON of FIG. 2) of the display module 11. The processor 12 may include one or more processors. In implementations with more than one processor, the processors may work individually, collectively or as part of a collective. For example, as part of a collective two out of three processors may operate together to execute instructions for an application.

The memory 13 may store data information for operation of the processor 12 or the display module 11. When the processor 12 executes an application stored in the memory 13, an input image data signal and/or a control signal may be transmitted to the display module 11, and the display module 11 may process the received signal and output image information through a display screen.

The power module 14 may include a power supply module, such as a power adapter or a battery device, and a power conversion module that converts power supplied by the power supply module to generate power for operation of the electronic device 10.

At least one of components of the electronic device 10 may be included in the display device according to embodiments of the present disclosure described above. In addition, some of individual modules functionally included in one module may be included in the display device, and other portions may be provided separately from the display device. For example, the display device may include the display module 11, and the processor 12, the memory 13, and the power module 14 may be provided in form of other devices within the electronic device 10 other than the display device.

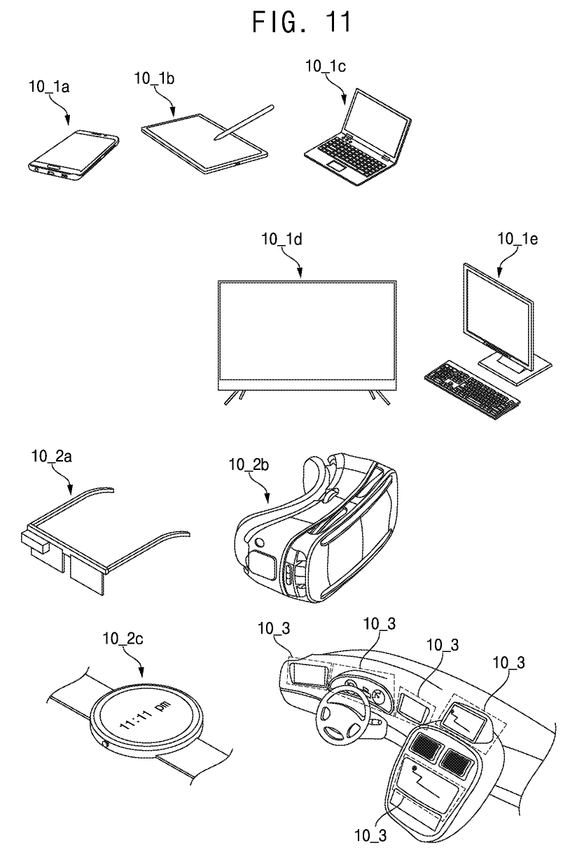

FIG. 11 is a schematic view illustrating electronic devices according to embodiments of the present disclosure.

Referring to FIG. 11, various electronic devices to which the display device according to an embodiment of the present disclosure is applied may include not only image display electronic devices such as a smartphone 10_1a, a tablet PC 10_1b, a laptop 10_1c, a TV 10_1d, and a desktop monitor 10_1e, but also wearable electronic devices including display modules, such as smart glasses 10_2a, a head-mounted display 10_2b, and a smart watch 10_2c, automotive electronic devices 10_3 including display modules, such as a Center Information Display (CID) arranged on a cluster, a center fascia, and dashboard of a car, and a room mirror display, or the like.

The present disclosure can be applied to various display devices and electronic devices. For example, the present disclosure is applicable to various display devices such as display devices for vehicles, ships and aircraft, portable communication devices, display devices for exhibition or information transmission, medical display devices, and the like.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A display device comprising:
a display panel including a plurality of pixels arranged in a first direction and a second direction intersecting the first direction; and
a gate driver configured to provide a gate signal to the display panel and the gate driver including a level shifter, the level shifter including:
a first level shift circuit;
a second level shift circuit adjacent to the first level shift circuit in the second direction;
a first electrostatic discharge element electrically connected to the first level shift circuit; and
a second electrostatic discharge element electrically connected to the second level shift circuit and adjacent to the first electrostatic discharge element in the first direction.

2. The display device of claim 1, wherein:
the first level shift circuit is arranged in a nth row of the plurality of pixels,
the second level shift circuit is arranged in a (n+1)th row of the plurality of pixels, and
the first electrostatic discharge element and the second electrostatic discharge element are arranged between the nth row and the (n+1)th row.

3. The display device of claim 2, wherein:
the first level shift circuit is electrically connected to a first pixel arranged in the nth row of the plurality of pixels, and
the second level shift circuit is electrically connected to a second pixel arranged in the (n+1)th row of the plurality of pixels.

4. The display device of claim 2, wherein:
the first electrostatic discharge element is arranged shifted toward the nth row, and
the second electrostatic discharge element is arranged shifted toward the (n+1)th row.

5. The display device of claim 1, wherein the first electrostatic discharge element and the second electrostatic discharge element are linearly arranged in the first direction.

6. The display device of claim 1, wherein:
each of the first level shift circuit and the second level shift circuit has a first length in the second direction,
each of the first electrostatic discharge element and the second electrostatic discharge element has a second length in the second direction, and
the second length is greater than the first length.

7. The display device of claim 1, wherein:
the first direction is a row direction, and
the second direction is a column direction.

8. The display device of claim 1, wherein the first electrostatic discharge element and the second electrostatic discharge element are arranged in alternating order in the first direction.

9. The display device of claim 8, wherein:
the first electrostatic discharge element includes a first sub-element and a second sub-element,
the second electrostatic discharge element includes a third sub-element and a fourth sub-element, and
the first sub-element, the third sub-element, the second sub-element, and the fourth sub-element are arranged in that sequence in the first direction.

10. The display device of claim 1, wherein the display panel includes a silicon wafer substrate.

11. An electronic device comprising:
a display device; and
one or more processors configured to provide a control signal and input image data to the display device,
wherein the display device includes:
a display panel including a plurality of pixels arranged in a first direction and a second direction intersecting the first direction; and
a gate driver configured to provide a gate signal to the display panel and the gate driver including a level shifter, the level shifter including:
a first level shift circuit;
a second level shift circuit adjacent to the first level shift circuit in the second direction;
a first electrostatic discharge element electrically connected to the first level shift circuit; and
a second electrostatic discharge element electrically connected to the second level shift circuit and adjacent to the first electrostatic discharge element in the first direction.

12. The electronic device of claim 11, wherein:
the first level shift circuit is arranged in a nth row of the plurality of pixels,
the second level shift circuit is arranged in a (n+1)th row of the plurality of pixels, and
the first electrostatic discharge element and the second electrostatic discharge element are arranged between the nth row and the (n+1)th row.

13. The electronic device of claim 12, wherein:
the first level shift circuit is electrically connected to a first pixel arranged in the nth row of the plurality of pixels, and
the second level shift circuit is electrically connected to a second pixel arranged in the (n+1)th row of the plurality of pixels.

14. The electronic device of claim 12, wherein:
the first electrostatic discharge element is arranged shifted toward the nth row, and
the second electrostatic discharge element is arranged shifted toward the (n+1)th row.

15. The electronic device of claim 11, wherein the first electrostatic discharge element and the second electrostatic discharge element are linearly arranged in the first direction.

16. The electronic device of claim 11, wherein:
each of the first level shift circuit and the second level shift circuit has a first length in the second direction,
each of the first electrostatic discharge element and the second electrostatic discharge element has a second length in the second direction, and
the second length is greater than the first length.

17. The electronic device of claim 11, wherein:
the first direction is a row direction, and
the second direction is a column direction.

18. The electronic device of claim 11, wherein the first electrostatic discharge element and the second electrostatic discharge element are arranged in alternating order in the first direction.

19. The electronic device of claim 18, wherein:
the first electrostatic discharge element includes a first sub-element and a second sub-element,
the second electrostatic discharge element includes a third sub-element and a fourth sub-element, and
the first sub-element, the third sub-element, the second sub-element, and the fourth sub-element are arranged in that sequence in the first direction.

20. The electronic device of claim 11, wherein the display panel includes a silicon wafer substrate.
